(19) United States
(12) Patent Application Publication
(10) Pub. No.: US 2007/0051995 A1
(43) Pub. Date: Mar. 8, 2007

(54) MOS transistor cell and semiconductor device

(76) Inventors: Masahiko Kumashiro, Osaka (JP); Tadashi Tanimoto, Shiga (JP)

Correspondence Address: MCDERMOTT WILL & EMERY LLP, 600 13TH STREET, N.W., WASHINGTON, DC, 20005-3096, US

(21) Appl. No.: 11/516,516

(22) Filed: Sep. 7, 2006

(30) Foreign Application Priority Data
Sep. 7, 2005 (JP) 2005-259564

(51) Int. Cl. H01L 29/94

(52) U.S. Cl. 257/296

(57) ABSTRACT

A MOS transistor cell having a salicide structure has a plurality of gate wires each formed as a straight line with a constant width. Each of the gate wires includes a P-channel gate terminal and an N-channel gate terminal. The P-side ends and the N-side ends of the gate wires are connected by means of respective two gate wire connecting portions at a boundary portion between the MOS transistor cell and another adjacent MOS transistor cell.

### CROSS-REFERENCE TO RELATED APPLICATIONS

The teachings of Japanese Patent Application JP 2005-259564, filed Sep. 7, 2005, are entirely incorporated herein by reference, inclusive of the claims, specification, and drawings.

### BACKGROUND OF THE INVENTION

The present invention relates to the layout of a gate and an active region layer in a MOS transistor cell having a salicide structure.

In a conventional MOS transistor, a continuous dummy region has been provided around a cell array pattern to shield it from peripheral influence, thereby providing stable gate size controllability. Conventionally, the permissible range for the size of a circuit pattern and variations therein has been relatively wide so that variations in gate size have not been a serious problem. However, with the recent rapid pattern miniaturization, the permissible range for size variations has been narrowed down and variations in gate size have greatly affected the performance and yield of a semiconductor device. In a microfabrication process, moreover, the configuration of a gate pattern is complicated for stable formation of salicide. The complicated configuration of the gate pattern becomes a factor which increases variations in pattern size and increases a time required for mask exposure or optical proximity correction (OPC).

In a conventional semiconductor device as shown in, e.g., FIG. 3, connecting portions 105 each having a width not less than the gate channel length L provide connection between a plurality of N-channel gate terminals 102 over a diffusion layer 101 which is located over a P-well and a plurality of P-channel gate terminals 104 over a diffusion layer 103 which is located over an N-well, thereby attempting stable formation of salicide on the gate. However, the transistor channel length L after photolithography has varied depending on the distance d between the gate channel of each of transistors and each of the corresponding connecting portions 105 and the shapes of the connecting portions 105. As a result, the transistor channel length in an image transferred onto a wafer has also varied, as shown in the circles of FIG. 4, and adversely affected transistor characteristics.

### SUMMARY OF THE INVENTION

In view of the foregoing, an object of the present invention is to improve the performance and yield of a semiconductor device by suppressing variations in transistor characteristics and gate channel length resulting from the circuit pattern layout of the semiconductor device.

As means for attaining the object, the present invention provides a MOS transistor cell having a salicide structure which comprises: a plurality of gate wires each formed as a straight line with a constant width and comprising a P-channel gate terminal and an N-channel gate terminal.

In the arrangement, the gate wires each formed as the straight line with the constant width and no indentation are laid over the N-P boundary so that the accuracy of gate channel length is improved.

Preferably, the MOS transistor cell further comprises: a gate wire connecting portion for connecting P-side ends of each of the plurality of gate wires; and another gate wire connecting portion for connecting N-side ends of each of the plurality of gate wires.

Preferably, the MOS transistor cell further comprises: a gate electrode provided in a boundary portion with an adjacent MOS transistor cell and connected to the two gate wire connecting portions.

In the arrangement, the cell is peripherally surrounded by the gate wires, the gate wire connecting portions, and the gate electrode so that the influence exerted on the inside of the cell from the peripheral configuration in an etching step and the like is reduced and therefore the accuracy of gate channel length in the cell is improved. In addition, since the boundary with the adjacent cell functions as a barrier surrounding the cell and is used as the electrode, the area occupied by the cells can be reduced.

Preferably, the MOS transistor cell further comprises: a dummy gate electrode provided in a boundary portion with another adjacent MOS transistor cell in opposing relation to the gate electrode and unconnected to the two gate wire connecting portions, wherein the gate electrode of the MOS transistor and a gate electrode of the adjacent MOS transistor are insulated from each other.

More preferably, when an MOS transistor cell is disposed adjacently to the dummy gate electrode, the dummy gate electrode is connected to the two gate wire connecting portions of the disposed MOS transistor cell and serves as the gate electrode thereof.

The present invention also provides a semiconductor device comprising: the MOS transistor cell described above; and a dummy diffusion layer which does not compose a MOS transistor and is provided in a boundary portion with an adjacent MOS transistor cell.

### BRIEF DESCRIPTION OF THE DRAWINGS

FIG. 1 is a structural view of a MOS transistor cell according to an embodiment of the present invention;

FIG. 2 is a view showing the MOS transistor cell according to the present invention after photolithography;

FIG. 3 is a structural view of a conventional MOS transistor cell; and

FIG. 4 is a view showing the conventional MOS transistor cell after photolithography.

### DESCRIPTION OF THE PREFERRED EMBODIMENTS

Referring to the drawings, the preferred embodiments of the present invention will be described herein below.

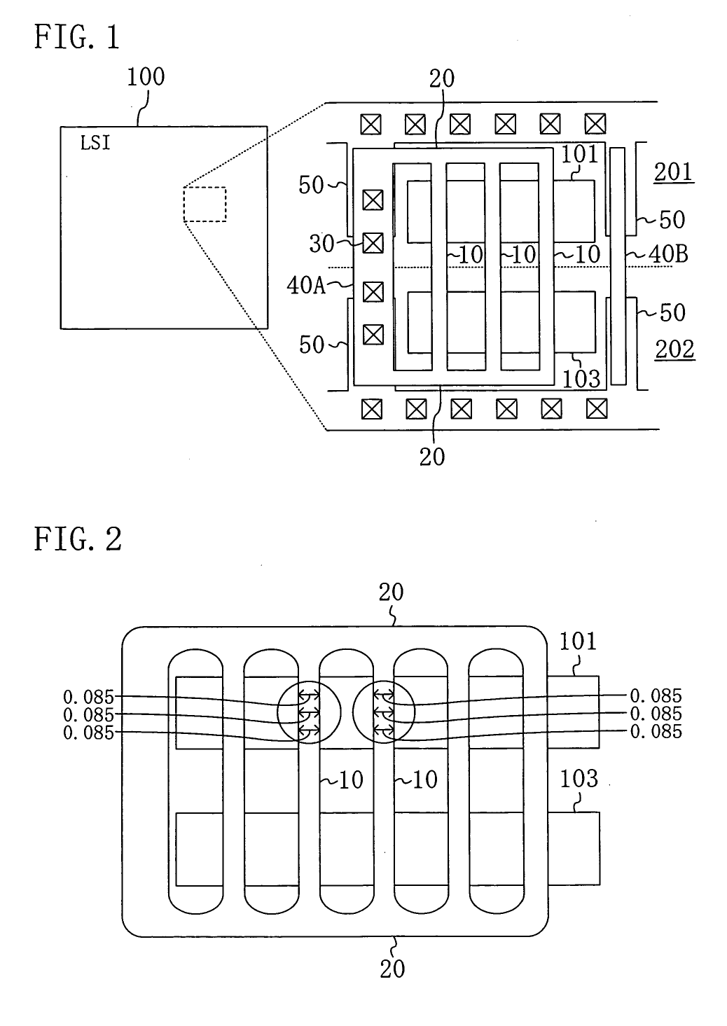

FIG. 1 shows a structure of a MOS transistor cell according to an embodiment of the present invention. A MOS transistor cell according to the present embodiment composes a part of a semiconductor device 100. For the sake of convenience, a description will be given herein below to the case where the MOS transistor cell according to the present invention is applied to a logic cell.

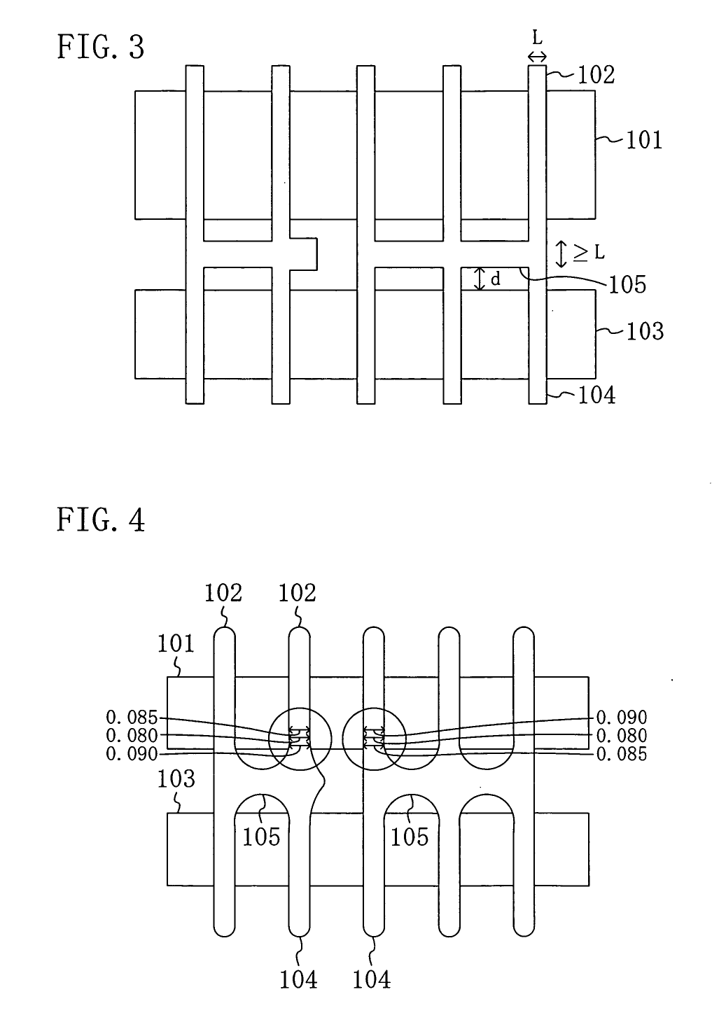

The MOS transistor cell according to the present embodiment comprises a plurality of gate wires 10 each formed as a straight line with a constant width and comprising a P-channel gate terminal and an N-channel gate terminal. Specifically, in the MOS transistor cell according to the present embodiment, each of the N-channel gate terminals and the corresponding P-channel gate terminal are connected in a single linear gate pattern (gate wire 10) with no indentation over the boundary between a P-well 201 and an N-well 202. In such a structure, however, the connecting portion between the N-channel and the P-channel is thinner than in the conventional structure (see, e.g., FIG. 3). Accordingly, breakage may occur in the gate wires each having a salicide structure. To prevent this, gate wire connecting portions 20 which connect the both ends of each of the gate wires 10 are provided around the cell to surround the transistor, respectively, as shown in FIG. 1.

FIG. 2 shows the MOS transistor cell according to the present invention after photolithography. As shown in the circles of FIG. 2, the transistor channel lengths in an image transferred onto a wafer are constant in the MOS transistor cell according to the present invention so that the transistor characteristics are stable. By providing the gate wire connecting portions 20, the gate electrodes are made redundant and stable current supply to the gate electrodes is allowed. In addition, the influence of variations in transistor channel length during an etching process resulting from a change in the pattern configuration of an adjacent cell can be reduced so that the transistor characteristics are stable.

Moreover, as shown in FIG. 1, the MOS transistor cell according to the present embodiment comprises a gate electrode 40A with a width which allows contact holes 30 to be located in a boundary portion with an adjacent cell (not shown). This provides stable salicide connection between the N-channel gate terminals and the P-channel gate terminals. Since the boundary with the adjacent cell is used as the electrode, the inter-cell space is used effectively and the area occupied by the cells can be reduced.

Besides, the MOS transistor cell according to the present embodiment comprises a dummy gate electrode 40B which is unconnected to the gate wire connecting portions 20. The dummy gate electrode 40B is provided in the boundary portion with another adjacent cell (not shown) in opposing relation to the gate electrode 40A. This prevents an inter-cell short circuit which may occur between the gate terminals of different cells when they are arranged adjacent to each other. When the other adjacent cell is disposed, the dummy gate electrode 40B functions as the gate electrode thereof.

Further, the MOS transistor cell according the present embodiment comprises dummy diffusion layers 50 each of which is located in the cell boundary portion and does not serve as the source or drain of a transistor. Each of the dummy diffusion layers 50 is an active region for, e.g., fixing a substrate potential over a power source line or a ground line. Since the dummy diffusion layers 50 function as shields in the etching process, the influence of size variations dependant on the pattern configuration of a peripheral cell is reduced so that processing accuracy for each of the diffusion layer 101 located over the P-well 201 and the diffusion layer 103 located over the N-well 202 is improved. In addition, the influence of STI (Shallow Trench Isolation) stress is reduced so that the transistor characteristics are stable.

The MOS transistor cell according to the present invention allows high-accuracy patterning and is useful for use in a liquid crystal television, a PDP, or the like. The MOS transistor cell according to the present invention is also useful for applications which require microfabrication, such as micromachining.

What is claimed is:

1. A MOS transistor cell having a salicide structure, the MOS transistor cell comprising:
a plurality of gate wires each formed as a straight line with a constant width and comprising a P-channel gate terminal and an N-channel gate terminal.

2. The MOS transistor cell of claim 1, further comprising:
a gate wire connecting portion for connecting P-side ends of each of the plurality of gate wires; and
another gate wire connecting portion for connecting N-side ends of each of the plurality of gate wires.

3. The MOS transistor cell of claim 2, further comprising:
a gate electrode provided in a boundary portion with an adjacent MOS transistor cell and connected to the two gate wire connecting portions.

4. The MOS transistor cell of claim 3, further comprising:
a dummy gate electrode provided in a boundary portion with another adjacent MOS transistor cell in opposing relation to the gate electrode and unconnected to the two gate wire connecting portions,
wherein the gate electrode of the MOS transistor and a gate electrode of the adjacent MOS transistor are insulated from each other.

5. The MOS transistor cell of claim 4, wherein, when an MOS transistor cell is disposed adjacently to the dummy gate electrode, the dummy gate electrode is connected to the two gate wire connecting portions of the disposed MOS transistor cell and serves as the gate electrode thereof.

6. A semiconductor device comprising:
the MOS transistor cell of claim 1; and
a dummy diffusion layer which does not compose a MOS transistor and is provided in a boundary portion with an adjacent MOS transistor cell.
